(19) United States
(12) Patent Application Publication
(10) Pub. No.: US 2015/0013604 A1
(43) Pub. Date: Jan. 15, 2015

(54) CHAMBER PRESSURE CONTROL APPARATUS FOR NEAR ATMOSPHERIC EPITAXIAL GROWTH SYSTEM

(71) Applicant: Applied Materials, Inc., Santa Clara, CA (US)

(72) Inventors: Toshiyuki NAKAGAWA, Narti-Shi (JP); Koji NAKANISHI, Sumida-Ku (JP); Tetsunori SASAYAMA, Kikuchi-Gun (JP); Masato ISHII, Sunnyvale, CA (US)

(21) Appl. No.: 14/305,022

(22) Filed: Jun. 16, 2014

Related U.S. Application Data
(60) Provisional application No. 61/844,328, filed on Jul. 9, 2013.

(51) Int. Cl. C30B 25/16

(52) U.S. Cl. CPC C30B 25/165
USPC 118/712

(57) ABSTRACT

The embodiments described herein generally relate to devices and systems for increased pressure control of near atmospheric deposition processes. Devices and systems disclosed herein generally include an exhaust apparatus for a processing chamber in connection with an automated valve which is positioned between the exhaust port and the abatement system. The processing chamber can generally be maintained at a pressure above atmospheric pressure while the automated valve controls the flow of gases leaving the chamber to keep the pressure constant in the chamber.

### CROSS-REFERENCE TO RELATED APPLICATIONS

This application claims benefit of U.S. Provisional Patent Application Ser. No. 61/844,328 (APPM/20745USL), filed Jul. 9, 2013, which is herein incorporated by reference.

### BACKGROUND

1. Field

Embodiments disclosed herein generally relate to methods for forming a silicon-containing layer. More particularly, embodiments herein relate to methods for forming a silicon-containing layer that may be used in thin film transistor (TFT) devices.

2. Description of the Related Art

Substrates, such as semiconductor substrates, can be subjected to an epitaxial growth process to form an epitaxial layer on a surface of the substrate. An exemplary epitaxial growth process includes flowing a process gas laterally over the surface of the substrate, and thermally decomposing the process gas on the surface of the substrate in order to deposit the epitaxial layer.

After deposition, the process gases in atmospheric pressure epitaxial growth systems are carried by gas flow to the reacting chamber and to facility exhaust through an abatement system. Due to this configuration, reacting chamber pressure is affected by surrounding atmospheric pressure and abatement system situation (i.e. byproduct clogging), thus there is risk for exhaust byproducts to back flow by facility pressure oscillations, and process results may differ by daily pressure fluctuation. Thus, it is important to be able to maintain the pressure inside the chamber constant.

One option for controlling pressure inside of a deposition chamber is through the use of a vacuum pump. However, atmospheric epitaxial growth systems configured with a vacuum pump can become unsafe due to faster pyrophoric byproducts build up and risk for explosion and fire in exhaust facilities. Therefore, atmospheric epitaxial growth systems are generally not configured with vacuum pump.

Others have applied a “cone-baffle” design in the exhaust line to control fluctuations in pressure in atmospheric epitaxial growth systems. This design can reduce the facility pressure oscillation effect to some extent, but not completely. Further, the “cone-baffle” design does not address daily pressure fluctuation.

Thus, there is a need for improved pressure control in atmospheric deposition systems and chambers.

### SUMMARY

The embodiments described herein generally relate to maintaining pressure in atmospheric epitaxial growth systems without the use of a vacuum pump.

In one embodiment, a pressure control system can include a processing chamber configured to process a substrate at a pressure at or above 760 Torr; an upper gas pipe in fluid connection with the processing chamber and configured to receive a processing gas from the processing chamber; a pressure detection device in fluid connection with the upper gas pipe and in connection with a first controller and configured to detect a pressure in the gas pipe and relay the pressure detected to the first controller; and a valve with a plurality of flow control states in fluid connection with the upper gas pipe and a lower gas pipe and in connection with the first controller, the valve configured to control the flow of the process gas from the upper gas pipe to the lower gas pipe based on each of the plurality of states and receive a signal from the first controller, wherein the signal received causes the valve to change to a selected state from the plurality of states.

In another embodiment, a processing chamber can include a chamber body with an exhaust port formed therein, a substrate support positioned within the chamber body and a pressure control exhaust. The pressure control exhaust can include an upper gas pipe in fluid connection with the processing chamber; a pressure detection device in fluid connection with the upper gas pipe and in connection with a first controller; a valve with a plurality of flow control states in fluid connection with the upper gas pipe and a lower gas pipe and in connection with the first controller; a second controller connected with the first controller; and an abatement system fluidly connected with the lower gas pipe.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope. The disclosure may admit to other equally effective embodiments.

FIG. 1A is a schematic, cross sectional view of a process chamber according to embodiments described herein; and

FIG. 1B is an expanded view of the exhaust system for processing chamber described in FIG. 1A.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments disclosed herein generally relate to devices and systems for increased pressure control of near atmospheric deposition processes. By controlling flow through the exhaust system, atmospheric pressure changes are not translated into the processing chamber. Thus, the process conditions of near-atmospheric systems can be better controlled. The embodiments disclosed herein are more clearly described with reference to the figures below.

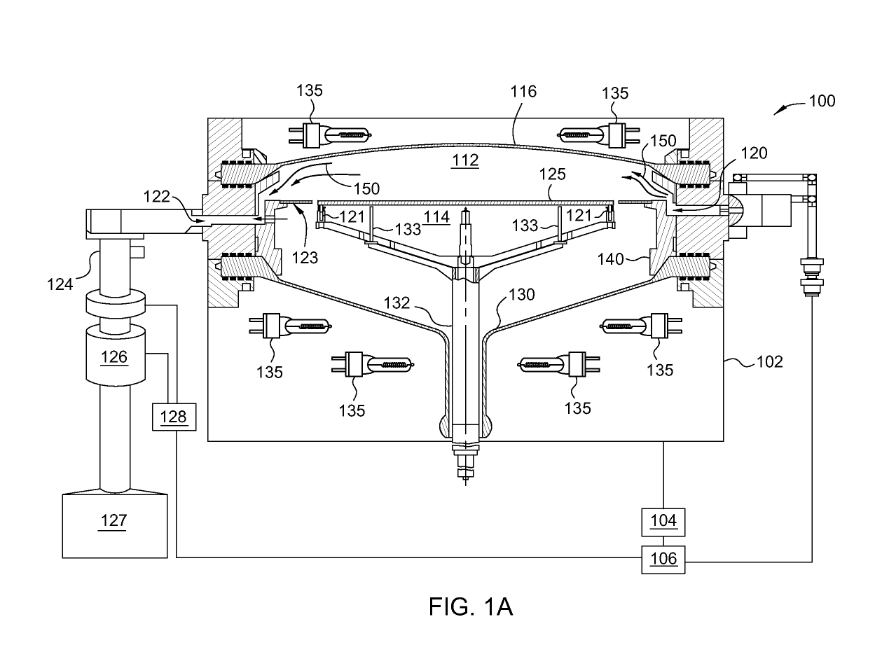

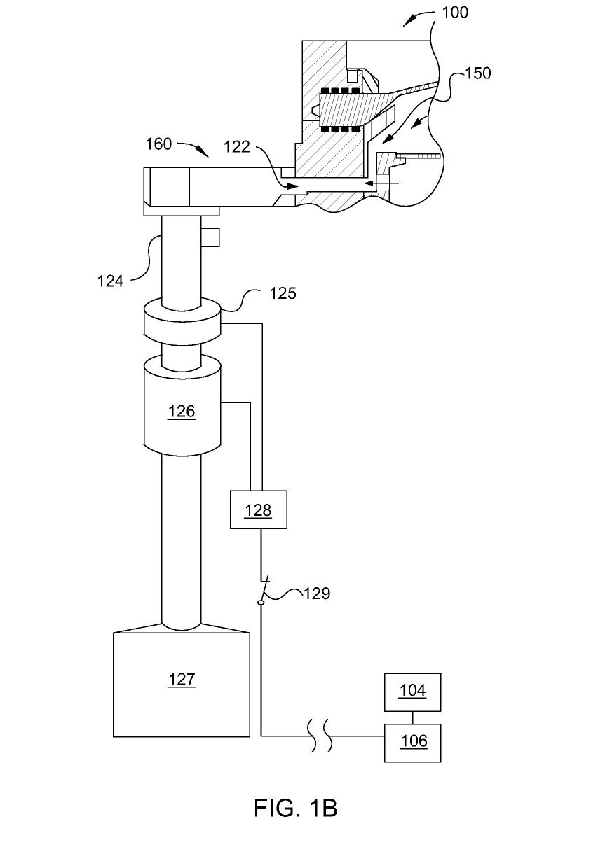

A variety of atmospheric CVD chambers may be modified to incorporate the embodiments described herein. In one embodiment, the atmospheric CVD chamber to be modified is the CVD chamber of the EPI CENTURA® near atmospheric CVD System, available from Applied Materials, Inc., of Santa Clara, Calif. The CENTURA® system is a fully automated semiconductor fabrication system, employing a single wafer, multi-chamber, modular design, which accommodates a wide variety of wafer sizes. In addition to the CVD chamber, the multiple chambers may include a pre-clean chamber, wafer orienter chamber, cooldown chamber, and independently operated loadlock chamber. The CVD chamber presented herein is shown in schematic in FIG. 1 is one embodiment and is not intended to be limiting of all possible embodiments. It is envisioned that other atmospheric or near atmospheric CVD chambers can be used in accordance with embodiments described herein, including chambers from other manufacturers.

Embodiments disclosed herein may be practiced in the CENTURA ACP® EPI chamber, available from Applied Materials, Inc. of Santa Clara, Calif. It is contemplated that other chambers available from other manufacturers may also benefit from embodiments disclosed herein.

FIG. 1A is a cross sectional view of a processing chamber 100 according to one embodiment. The processing chamber 100 comprises a chamber body 102, support systems 104, and a chamber controller 106. The chamber body 102 includes an upper portion 112 and a lower portion 114. The upper portion 112 includes the area within the chamber body 102 between the upper dome 116 and the substrate 125. The lower portion 114 includes the area within the chamber body 102 between a lower dome 130 and the bottom of the substrate 125. Deposition processes generally occur on the upper surface of the substrate 125 within the upper portion 112. The substrate 125 is supported by support posts 121 disposed beneath the substrate 125.

An upper liner 118 is disposed within the upper portion 112 and is adapted to prevent undesired deposition onto chamber components. The upper liner 118 is positioned adjacent to a ring 123 within the upper portion 112. The processing chamber 100 includes a plurality of heat sources, such as lamps 135, which are adapted to provide thermal energy to components positioned within the processing chamber 100. For example, the lamps 135 may be adapted to provide thermal energy to the substrate 125 and the ring 123. The lower dome 130 may be formed from an optically transparent material, such as quartz, to facilitate the passage of thermal radiation therethrough.

The chamber body 102 includes an inlet 120 and an exhaust port 122 formed therein. The inlet 120 may be adapted to provide a process gas 150 therethrough into the upper portion 112 of the chamber body 102, while an exhaust port 122 may be adapted to exhaust a process gas 150 from the upper portion 112. In such a manner, the process gas 150 may flow parallel to the upper surface of the substrate 125. Thermal decomposition of the process gas 150 onto the substrate 125 to form an epitaxial layer on the substrate 125 is facilitated by the lamps 135.

A substrate support assembly 132 is positioned in the lower portion 114 of the chamber body 102. The substrate support 132 is illustrated supporting a substrate 125 in a processing position. The substrate support assembly 132 includes a plurality of support pins 121 and a plurality of lift pins 133. The lift pins 133 are vertically actuatable and are adapted to contact the underside of the substrate 125 to lift the substrate 125 from a processing position (as shown) to a substrate removal position. The components of the substrate lift assembly 132 can be fabricated from quartz, silicon carbide, graphite coated with silicon carbide or other suitable materials.

The ring 123 can removably disposed on a lower liner 140 that is coupled to the chamber body 102. The ring 123 can be disposed around the internal volume of the chamber body 102 and circumscribes the substrate 125 while the substrate 125 is in a processing position. The ring 123 can be formed from a thermally-stable material such as silicon carbide, quartz or graphite coated with silicon carbide. The ring 123, in combination with the position of the substrate 125, can separate the volume of the upper potion 112. The ring 123 can provide proper gas flow through the upper portion 112 when the substrate 125 is positioned level with the ring 123. The separate volume of the upper portion 112 enhances deposition uniformity by controlling the flow of process gas as the process gas is provided to the processing chamber 100.

The support system 104 includes components used to execute and monitor pre-determined processes, such as the growth of epitaxial films in the processing chamber 100. The support system 104 includes one or more of gas panels, gas distribution conduits, power supplies, and process control instruments. A chamber controller 106 is coupled to the support system 104 and is adapted to control the processing chamber 100 and support system 104. The chamber controller 106 includes a central processing unit (CPU), a memory, and support circuits. Instructions resident in chamber controller 106 may be executed to control the operation of the processing chamber 100. Processing chamber 100 is adapted to perform one or more film formation or deposition processes therein. For example, a silicon carbide epitaxial growth process may be performed within processing chamber 100. It is contemplated that other processes may be performed within processing chamber 100.

FIG. 1B is an expanded view of the exhaust system 160 for processing chamber 100. The exhaust system 160 begins at the exhaust port 122 which receives the process gas 150 from the upper region 112 of the processing chamber 100. The exhaust port 122 is connected to an exhaust line 124. The exhaust line 124 is fluidly connected with a pressure detection device 125, a valve 126 and an abatement system 127. The pressure detection device 125 can be a device for determining the pressure in the line. In one example, the pressure detection device 125 is a transducer, such as a vacuum transducer. The pressure detection device 125 can detect a wide variety of pressures and pressure ranges. In one embodiment, the pressure detection device 125 can detect pressures greater than or equal to about 1 torr, such as pressures between about 1 torr and 1000 torr. In one embodiment, the pressure detection device 125 can detect pressure within the operable pressure range of the processing chamber 100.

The pressure detection device 125 is connected with a local controller 128. The local controller 128 receives the signal from the pressure detection device 125 regarding the pressure inside of exhaust line 124. The local controller 128 can have a set point. The set point is defined as a pressure above which or below which the valve 126 is open, closed or some state in between. The set point of the local controller 128 can be a pressure from about 750 Torr to about 800 Torr, such as a pressure between 780 Torr.

The local controller 128 can be connected with the chamber controller 106 and the valve 126. The local controller 128 includes instructions which when run can be used to estimate pressure and flow based available information such as the pressure measurement received from the pressure detection device 125, the maximum and minimum flow rate through the valve 126 based on the state of the valve 126, the diameter of the exhaust pipes and other factors.

Upon reaching the set point, the local controller 128 can send a signal to the chamber controller 106. The chamber controller 106 can then send a response to the local controller 128 to alter fluid access through the valve 126, which is in response to the signal received from the local controller 128. Altering fluid access can include opening the valve 126, closing the valve 126 or changing the size or shape of the fluid opening through the valve 126.

The ability to alter fluid access will be dependent on the shape and design of the valve 126. The valve 126 can be any valve which is capable of withstanding the processing conditions present in the exhaust tube 124 prior to the abatement system 127. In one embodiment, the valve 126 is a pressure control valve or a throttle valve. Valves which can be modified to perform the functionality described in the system above include the MKS Type T3BI Intelligent Exhaust Throttle Valve available from MKS Instruments located in Andover, Mass. It is envisioned that other valves including valves of other makes and from other manufacturers can be used or adapted to perform the functions described herein. Upon receiving a signal from the chamber controller 106 the local controller 128 provides a subsequent signal to the valve 126 altering fluid access as described above.

During operation according to one embodiment, the process gas 150 will exit from the processing chamber 100 and enter the exhaust system 160 through the exhaust port 122. The exhaust port 122 allows the process gas 150 to flow through the exhaust pipe 124 and through the pressure detection device 125. The pressure detection device 125 sends a signal to the local controller 128, wherein the signal conveys the local pressure in the exhaust pipe 124. Once the local pressure crosses the set point, the local controller 128 sends a signal to the chamber controller 106. The chamber controller 106 then sends a signal to the local controller 128 to alter fluid access through the valve 126. The valve 126 is then closed or restricted if the pressure is below the set point and the valve 126 is opened if the pressure is greater than the set point such that the pressure inside the exhaust pipe 124, and thus inside the process chamber 100, is maintained at a pressure above standard atmospheric pressure. The pressure above standard atmospheric pressure can be any pressure above 760 Torr, such as a pressure between 780 Torr and 800 Torr.

In further embodiments, the chamber controller 106 is connected directly to the valve 126 such that the local controller 128 is not involved or not directly involved in closing the valve 126. As well, the exhaust system 160 can include a control switch 129. The control switch 129 is a switch to set the valve position without further automated control from either the local controller 128 or the chamber controller 106. The control switch 129 can be either an analog switch or a digital switch. The control switch 129 can be controlled manually or digitally. Though depicted here as being positioned between the local controller 128 and the chamber controller 106, it is understood that the control switch 129 can be positioned anywhere along the pathway between the chamber controller 106 and the valve 129, including being part of the valve 129, the local controller 128 and/or the chamber controller 106.

Once the valve 126 has been properly controlled as described above, the process gas 150 will either flow through the valve 126 or remain in the exhaust pipe behind the valve 126. If the valve 126 is in a restricted or open position, the process gas 124 will flow through the remaining portion of the exhaust pipe 124 to the abatement system 127 for further processing of the process gas 124.

It is believed that the process chamber 100 should be maintained at a pressure slightly above atmospheric pressure to allow the exhaust system 160 to maintain the pressure constant in the process chamber 100. When the exhaust system 160 allows free flow of the process gas 150 to the environment, the atmospheric pressure around the process chamber 100 can affect the pressure inside the process chamber 100. Subtle atmospheric pressure differences, due to natural changes in atmospheric pressure and the like, can cause changes in the deposited product on a substrate 125. By using gas flow inside the process chamber 100 and the valve 126 to maintain the pressure inside the process chamber 100 slightly above atmospheric pressure, the pressure before the valve 126 is always be higher than the pressure after the valve 126. Thus, fluctuations in pressure will not be translated into the chamber beyond the valve 126.

Abatement systems generally create a slightly negative pressure. Thus, current designs can employ a manual valve at the abatement system inlet. The valve position in these embodiments is generally set in a partially closed fixed position to prevent the abatement system from significantly affecting the reacting chamber pressure. With the valve 126 positioned and controlled as described above, this manual valve can be fully opened or removed entirely to create better and real time control of pressure in the processing chamber 100.

Embodiments disclosed herein relate to devices and systems for increased pressure control of near atmospheric deposition processes. By controlling the flow exiting the exhaust system, the pressure of the processing chamber can be maintained without harmful or explosive build-up as seen with some vacuum pump epitaxial systems. Thus, the overall quality and uniformity of deposition products as formed in near-atmospheric deposition systems can be increased.

While the foregoing is directed to embodiments described herein, other and further embodiments may be devised without departing from the basic scope thereof.

1. An pressure control system, comprising:
a processing chamber with a processing volume for processing a substrate at a pressure at or above 760 Torr;
an upper gas pipe in fluid connection with the processing chamber, the upper gas pipe receiving a processing gas from the processing chamber;
a pressure detection device in fluid connection with the upper gas pipe and in connection with a first controller, the pressure detection device:
detecting a pressure in the gas pipe; and
relaying the pressure detected to the first controller; and
a valve with a plurality of flow control states in fluid connection with the upper gas pipe and a lower gas pipe and in connection with the first controller, the valve:
controlling the flow of the process gas from the upper gas pipe to the lower gas pipe based on each of the plurality of states; and
receiving a signal from the first controller, wherein the signal received causes the valve to change to a selected state from the plurality of states.

2. The pressure control system of claim 1, wherein the first controller has a set point and:
changes the state of the valve to a state which allows more of the process gas to flow from the upper gas pipe to the lower gas pipe when the temperature is above the set point; and
changes the state of the valve to a state which allows less of the process gas to flow from the upper gas pipe to the lower gas pipe when the temperature is below the set point.

3. The pressure control system of claim 2, wherein the set point is between 780 Torr and 800 Torr.

4. The pressure control system of claim 1, wherein the first controller is in connection with a second controller and the second controller:
receives a signal from the first controller regarding the pressure detected by the pressure detection device; and
sends a second signal to the first controller or the valve to cause the valve to change to a selected state from the plurality of states.

5. The pressure control system of claim 1, wherein the pressure detection device detects pressure between 1 Torr and 1000 Torr.

6. The pressure control system of claim 1, wherein the valve is a throttle valve.

7. The pressure control system of claim 1, wherein the valve is maintained in either in the open state or closed state.

8. The pressure control system of claim 1, further comprising a control switch configured to maintain the valve in the open state.

9. A processing chamber, comprising:
a chamber body with an exhaust port formed therein;
a substrate support positioned within the chamber body;
a pressure control exhaust comprising:
an upper gas pipe in fluid connection with the processing chamber;
a pressure detection device in fluid connection with the upper gas pipe and in connection with a first controller;
a valve with a plurality of flow control states in fluid connection with the upper gas pipe and a lower gas pipe and in connection with the first controller;
a second controller connected with the first controller; and
an abatement system fluidly connected with the lower gas pipe.

10. The processing chamber of claim 9, wherein the first controller comprises a set point between 780 Torr and 800 Torr.

11. The processing chamber of claim 9, wherein the second controller sends a signal to the first controller or the valve, to cause the valve to change to a selected state from the plurality of states based on a detected pressure.

12. The processing chamber of claim 9, wherein the pressure detection device detects pressure between 1 Torr and 1000 Torr.

13. The processing chamber of claim 9, wherein the valve is a throttle valve.

14. The processing chamber of claim 9, wherein the valve is maintained in either in the open state or closed state.

15. The processing chamber of claim 9, further comprising a control switch.

16. A processing chamber, comprising:
a chamber body having a plurality of chambers walls, an upper dome and a lower dome, the chamber body having an exhaust port formed therein;
a substrate support positioned within the chamber body;
one or more lamps adapted to provide thermal energy to the substrate support;
a pressure control exhaust comprising:
an upper gas pipe in fluid connection with the processing chamber;
a pressure detection device in fluid connection with the upper gas pipe and in connection with a first controller, the pressure detection device detecting a pressure in the upper gas pipe or the lower gas pipe between 1 Torr and 1000 Torr;
a valve with a plurality of flow control states in fluid connection with the upper gas pipe and a lower gas pipe and in connection with the first controller;
a second controller connected with the first controller;
a control switch in connection with the valve; and
an abatement system fluidly connected with the lower gas pipe.

17. The processing chamber of claim 16, wherein the first controller comprises a set point between 780 Torr and 800 Torr.

18. The processing chamber of claim 16, wherein the second controller sends a signal to the first controller or the valve, to cause the valve to change to a selected state from the plurality of states based on a detected pressure.

19. The processing chamber of claim 16, wherein the valve is a throttle valve.

20. The processing chamber of claim 16, wherein the pressure detection device is a vacuum transducer.
